(19) United States
(12) Patent Application Publication
(10) Pub. No.: US 2010/0140774 A1
(43) Pub. Date: Jun. 10, 2010

(54) METHOD OF PRODUCING EXTERNAL PADS ON A SEMICONDUCTOR DEVICE, AND SEMICONDUCTOR DEVICE

(75) Inventors: Sebastien Pruvost, Froges (FR); Laurent Chabert, Grenoble (FR)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: STMicroelectronics S.A., Montrouge (FR)

(21) Appl. No.: 12/629,785

(22) Filed: Dec. 2, 2009

(30) Foreign Application Priority Data
Dec. 5, 2008 (FR) FR 08 58322

(51) Int. Cl. H01L 25/065; H01L 21/768; H01L 23/488; H01L 23/52

(52) U.S. Cl. 257/686; 438/612; 257/773; 438/666; 257/E21.575; 257/E23.023; 257/E23.141; 257/E25.013

(57) ABSTRACT

External electrical connection pads are provided on a semiconductor device. A well is formed in an outer surface for the semiconductor device to at least partially expose an internal electrical connection pad. An electrical connection tab is formed which has an internal branch extending over the internal pad, an external branch extending over a top of the outer surface and extending from one side edge of the well, and a linking branch extending over a sidewall of the wells between the external branch and the internal branch.

### PRIORITY CLAIM

This application claims priority from French Application for Patent No. 08 58322 filed Dec. 5, 2008, the disclosure of which is incorporated by reference.

### TECHNICAL FIELD

The present invention relates to the field of semiconductor devices.

### BACKGROUND

Usually, semiconductor devices such as integrated-circuit chips have flat electrical connection pads placed with predetermined pitches. These pads are produced in a last metallization level of the integrated circuit chip. In one known case, electrical connection balls may be bonded to the pads, via approximately spherical caps, the diameter of the balls and the pitch of the pads being interdependent. In another known case, ball-shaped ends of electrical connection wires may be bonded to the pads, the diameter of the balls and the pitch of the pads also being interdependent. Furthermore, both the balls and the wires produce losses and perturbations that often are not negligible.

### SUMMARY

Embodiments herein provide a method of producing external electrical connection pads on a semiconductor device.

This method may comprise: the production of wells in an outer surface of the device which at least partially expose internal electrical connection pads of this device; and the production of electrical connection tabs having respectively branches, extending over the internal pads, external branches, extending over the outer surface of the component and over part of the perimeter of the wells, and linking branches, extending over the sidewalls of the wells.

The production of the tabs may comprise: the formation of a mask on the outer surface of the device and in the wells; the formation of holes in this mask corresponding to the tabs to be obtained; the formation of the tabs in the holes of the mask; and the removal of the mask.

The tabs may be produced by chemical deposition.

The method may comprise: the formation of a last metallization level, which includes the internal pads on an anterior surface; the formation of an outer surface layer on the last metallization level; and the formation of the wells in this outer surface layer.

The invention also provides a semiconductor device which may comprise: internal pads formed below and at some distance from an outer surface; wells provided above the internal pads and at least partially exposing the internal pads; and tabs having, respectively, internal branches extending over the internal pads, external branches extending over the outer surface and over part of the perimeter of the wells, and linking branches extending over the sidewalls of the wells.

The external branches of the tabs may protrude from said outer surface.

The external branches of the tabs may lie on one side of the wells.

The external branches of the tabs may have parallel sides.

Embodiments further provide an assembly comprising a first semiconductor device, such as the one above, and a second device having electrical connection pads, these pads being bonded to the external branches of the tabs of the semiconductor device.

### BRIEF DESCRIPTION OF THE DRAWINGS

A semiconductor device and method for fabricating it will now be described by way of non-limiting examples and illustrated by the accompanying drawings, in which:

FIG. 1 shows a top view of a semiconductor device;

FIG. 2 shows a cross section on lines II-II of the semiconductor device of FIG. 1;

FIG. 3 shows one step in the production of the above semiconductor device; and

FIG. 4 shows a cross section of an assembly comprising the above semiconductor device.

### DETAILED DESCRIPTION OF THE DRAWINGS

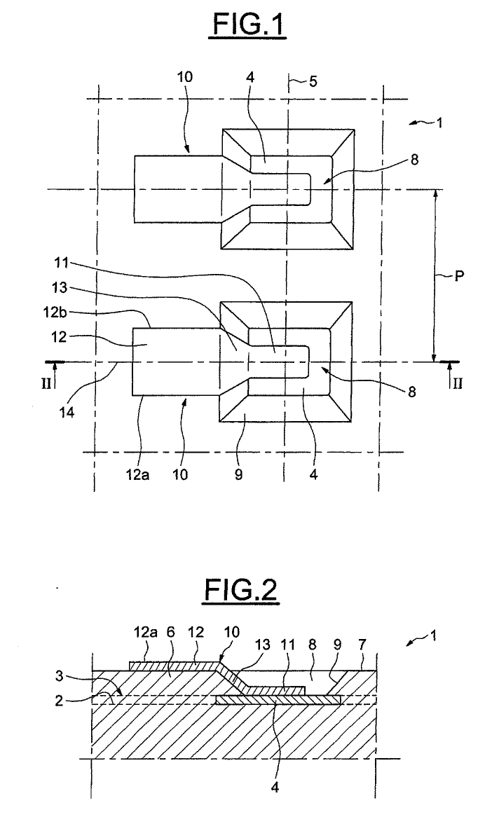

Reference is made to FIGS. 1 and 2. A semiconductor device 1, in particular an integrated-circuit chip, comprises, on an anterior surface 2, a last metallization level 3 comprising a plurality of internal electrical connection pads 4 connected to the integrated circuit (not shown) which is formed beneath the anterior surface 2. In general, the internal pads 4 are placed in one or more rows along which they are aligned and established with a regular pitch. FIG. 1 shows two internal pads 4 in a row along a direction 5 and established with a pitch P.

The semiconductor device 1 also has a surface layer 6 formed on the anterior surface 2 and covering the last metallization level 3, this surface layer 6 having an outer surface 7.

Provided in the outer surface 7 and through the surface layer 6 are wells 8 which expose, preferably partially, the internal pads 4. These wells 8 may be produced by etching through a mask. The wells 8 may have sloping sidewalls 9, for example in the form of four-sided pyramids.

The semiconductor device 1 furthermore includes flat electrical connection tabs 10 which have, respectively, internal branches 11 extending over the internal pads 4, external branches 12 extending over the outer surface 7, and linking branches 13 extending over the sidewalls 9 of the wells 4. The external branches 12 thus have outer surfaces 12a of external electrical connection, which are capable of receiving any means for electrically connecting the integrated circuit to another device.

The external branches 12 extend over part of the perimeter of the wells 8 and, in the example shown, are formed on one side of the wells 8. The linking branches 13 may extend over part of the perimeter of the wells 8 and, in the examples shown, are on the same side of the sidewalls 9 of the wells 8. The internal branches 11 may partially cover the exposed parts of these internal pads 4.

In the example shown, the branches 11, 12 and 13 constituting the tabs 10 may be aligned one after another and placed in such a way that the tabs 10 extend along directions 14 that are perpendicular to the direction 5.

The external branches 12 of the tabs 10 may be established with the pitch P of the internal pads 4.

In a variant, the external branches 12 of the tabs 10 may have parallel opposed edges 12a and 12b which are parallel to the direction 14, it being possible for the width between corresponding opposed edges 12a and 12b and for the distance between the external branches 12 of two adjacent tabs 10 to be matched to the pitch P between the internal pads 4.

For example, the width of the external branches 12 (between edges 12a and 12b) may be approximately equal to the corresponding width of the entrance of the wells 8. Thus, the external branches 12 may be included within an angle, taken at the center of the internal pads 4, of less than 90°.

For example, the corresponding width of the internal branches 11 may be smaller than the width of the external branches 12. The corresponding width of the linking branches may decrease from the external branches 12 to the internal branches 11.

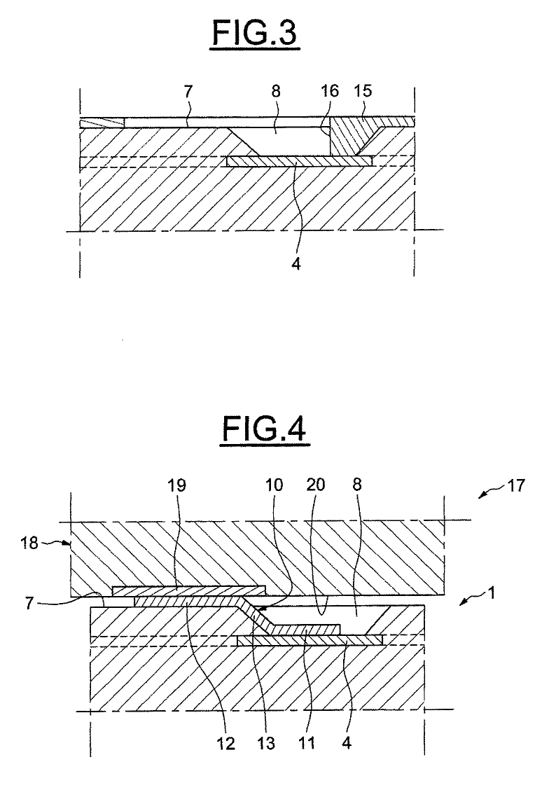

As shown in FIG. 3, the tabs 10 may be produced in the following manner. A mask 15 is deposited on the outer surface 7 and in the wells 8. Holes 16 corresponding to the location of the tabs 10 to be obtained are produced in this mask 15. A metal, for example copper or aluminum, is deposited on the bottom of the holes 16, for example by chemical deposition. Lastly, the mask 15 is removed.

Tabs 10 are therefore obtained which have their internal branches 11 protruding from the internal pads 4, their external branches 12 protruding from the outer surface 7, and their linking branches 13 protruding from the sidewalls 9 of the wells 8.

FIG. 4 shows an assembly 17 comprising a first device, consisting of the semiconductor device 1 as described above, and a second device 18, which has external pads 19 in an outer surface 20, this second device 18 possibly being an electrical connection substrate or another semiconductor device.

The flat external pads 19 of the second device are placed so as to be flat on the flat protruding external branches 12 of the tabs 10 of the semiconductor device 1, it being possible for the pads 19 and the branches 12 to be of very similar and corresponding dimensions. The pads 19 may be fastened to the branches 12 by thermosonic bonding.

The semiconductor device 1 could in particular have the following variants.

The external branches 12 of the tabs 10 could extend over a larger part of the perimeter of the wells 8, for example overhanging the two adjacent sides.

The linking branches 13 of the tabs 10 could extend over a larger part of the perimeter of the wells 8, for example overhanging the two adjacent sides or going around them.

The internal branches 11 of the tabs 10 could completely cover the internal pads 4.

The wells 8 could be offset along the direction 14.

The external branches 12 of the tabs 10 could be oriented so that some of them lie along one direction and others along the opposite direction, or perpendicularly, or making other angles, depending for example on relative dispositions of the internal pads 4.

A well common to a plurality of internal pads 4 could be provided and a plurality of tabs 10 could be associated with this common well, these tabs 10 being spaced apart along the periphery of this common well.

The semiconductor device 1 that has been described above may reduce the electrical losses and perturbations in its connections with another device 18 and may reduce the pitches P between these connections, possibly then allowing the pitch density to be increased.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A method of producing external electrical connection pads on a semiconductor device, comprising:
producing at least one well in an outer surface of a semiconductor device, that well at least partially exposing an internal electrical connection pad of the semiconductor device; and
producing an electrical connection tab having an internal branch which extends over the internal electrical connection pad within the well, an external branch which extends over the outer surface of the semiconductor device at a perimeter of the well, and a linking branch which extends over a sidewall of the well between the internal branch and external branch.

2. The method according to claim 1, wherein producing the electrical connection tab comprises: forming a mask on the outer surface of the semiconductor device and in the well; forming a hole in the mask corresponding to a location of the tabs to be obtained; depositing conductor in the hole of the mask to form the tab; and removing the mask.

3. The method according to claim 2, wherein depositing comprises a chemical deposition.

4. The method according to claim 1, further comprising: forming a last metallization level of the semiconductor device, that last metallization level including the internal pads on an anterior surface; forming an outer surface layer on the last metallization level; and forming the well in this outer surface layer.

5. A semiconductor device, comprising:
an outer surface layer;
an internal pad formed below and at some distance from a top surface of the outer surface layer;
a well provided in the outer surface layer above the internal pad and at least partially exposing the internal pad; and
a tab having an internal branch extending over the internal pad within the well, an external branch extending over the top surface of the outer surface layer at a perimeter of the well, and a linking branch which extends over a sidewall of the well between the internal branch and external branch.

6. The device according to claim 5, wherein the external branch of the tab protrudes from the top surface of the outer surface layer.

7. The device according to claim 5, wherein the external branch of the tab extend from one side edge of the well.

8. The device according to claim 5, wherein the external branch of the tab (10) has a pair of parallel sides.

9. An assembly, comprising:
a first semiconductor device, comprising:
an outer surface layer;
an internal pad formed below and at some distance from a top surface of the outer surface layer;
a well provided in the outer surface layer above the internal pad and at least partially exposing the internal pad; and
a tab having an internal branch extending over the internal pad within the well, an external branch extending over the top surface of the outer surface layer at a perimeter of the well, and a linking branch which extends over a sidewall of the well between the internal branch and external branch; and
a second semiconductor device having an electrical connection pad, the second semiconductor device being positioned in a stack with the first semiconductor device such that the electrical connection pad of the second semiconductor device is bonded to the external branch of the tab of the first semiconductor device.
